(19) United States
(12) Patent Application Publication
(10) Pub. No.: US 2026/0164718 A1
(43) Pub. Date: Jun. 11, 2026

(54) ARRAY SUBSTRATE, DISPLAY PANEL, AND METHOD FOR MANUFACTURING ARRAY SUBSTRATE

(71) Applicants: Beijing BOE Technology Development Co., Ltd., Beijing (CN); BOE Technology Group Co., Ltd., Beijing (CN)

(72) Inventors: Wei LIU, Beijing (CN); Wei YANG, Beijing (CN); Fengjuan LIU, Beijing (CN); Ce NING, Beijing (CN); Cheng XU, Beijing (CN); Dandan ZHOU, Beijing (CN); Haoran WANG, Beijing (CN); Jianye ZHANG, Beijing (CN)

(73) Assignees: Beijing BOE Technology Development Co., Ltd., Beijing (CN); BOE Technology Group Co., Ltd., Beijing (CN)

(21) Appl. No.: 18/695,370

(22) PCT Filed: Aug. 29, 2023
(86) PCT No.: PCT/CN2023/115609

§ 371 Date: Feb. 27, 2026

(51) Int. Cl. H10D 30/67; H10D 30/01; H10D 86/40; H10D 86/60; H10K 59/121

(52) U.S. Cl. CPC H10D 30/6736; H10D 30/0318; H10D 30/6728; H10D 30/6731; H10D 30/6755; H10D 30/6757; H10D 86/423; H10D 86/431; H10D 86/60; H10K 59/1213

(57) ABSTRACT

The present disclosure provides an array substrate, a display panel, and a method for manufacturing the array substrate, belonging to the field of display technologies. In the array substrate, a first electrode having a higher voltage in the first electrode and a second electrode of the transistor is disposed between an active layer and a base in a lower lap manner, and the second electrode having a lower voltage is disposed on a first insulating layer in an upper lap manner or disposed below the first insulating layer in the lower lap manner. When the second electrode is disposed in the upper lap manner, the problem that the transistor cannot operate normally due to the too large resistance at the second electrode can be avoided. When the second electrode is disposed in the lower lap manner, the risk that the active layer is easily damaged at a via hole when the active layer is in contact with the electrode through the via hole can be avoided, thereby solving the problem of the poor performance of the array substrate in the related art, and improving the performance of the array substrate.

### TECHNICAL FIELD

The present disclosure relates to the field of display technologies, and in particular, relates to an array substrate, a display panel, and a method for manufacturing the array substrate.

### BACKGROUND

A display panel is a device capable of achieving a display function. The display panel includes an array substrate and a display structure, and the array substrate is configured to control the display structure.

At present, the array substrate includes a base and a plurality of thin film transistors (TFTs) arranged in an array on the base. The thin film transistor includes a source and a drain which are disposed on the base, a buffer layer covering the source and the drain, an active layer disposed on the buffer layer, a gate insulating layer covering the active layer, and a gate disposed on the gate insulating layer. The active layer is in contact with the source and the drain through a via hole in the buffer layer, and the gate can control the active layer, so that the source and the drain are coupled through the active layer.

However, in the above thin film transistor, the source and the drain may not be coupled under some situations, resulting in poor performance of the array substrate.

### SUMMARY

Embodiments of the present disclosure provide an array substrate, a display panel, and a method for manufacturing the array substrate. The technical solutions are as follows.

According to a first aspect of the present disclosure, an array substrate is provided. The array substrate includes: a base and a plurality of transistors disposed on the base, wherein the transistor includes:
a first electrode disposed on the base;
an active layer disposed on the base on which the first electrode is provided, wherein the active layer at least covers a partial region of the first electrode;
a first insulating layer disposed on a side of the active layer away from the base, wherein the first insulating layer is provided with a second electrode opening, wherein an orthographic projection of the second electrode opening on the base and an orthographic projection of the active layer on the base have a first overlapping region;
a gate disposed on a side of the first insulating layer away from the base, wherein the gate is disposed on the first insulating layer, and an orthographic projection of the gate on the base and the orthographic projection of the active layer on the base have a second overlapping region; and
a second electrode disposed on the side of the first insulating layer away from the base or disposed on a side of the first insulating layer close to the base;
wherein the orthographic projection of the second electrode opening on the base overlaps with an orthographic projection of the second electrode on the base, the second electrode is in contact with the active layer, and when the transistor operates, a voltage of the first electrode is greater than a voltage of the second electrode.

In some embodiments, in the case that the second electrode is disposed on the side of the first insulating layer away from the base, the second electrode is in contact with the active layer through the second electrode opening; and the first insulating layer is further provided with a first electrode opening, wherein an orthographic projection of the first electrode opening on the base and the orthographic projection of the active layer on the base have a third overlapping region, and the third overlapping region overlaps with the first electrode;

the first insulating layer includes a gate insulating layer disposed between the first electrode opening and the second electrode opening, and an orthographic projection of an edge, covered by the active layer, of the first electrode on the base is within an orthographic projection of the gate insulating layer on the base.

In some embodiments, a first distance between an edge of the gate insulating layer at the first electrode opening and the gate in a first direction is positively correlated with a mobility of the active layer, wherein the first direction is an arrangement direction of the first electrode opening and the second electrode opening;

a second distance between an edge of the gate insulating layer at the second electrode opening and the gate in the first direction is positively correlated with the mobility of the active layer.

In some embodiments, the first distance ranges from 2 μm to 4 μm, and the second distance ranges from 2 μm to 4 μm.

In some embodiments, the array substrate includes a buffer layer disposed between the first electrode and the base, wherein the first electrode and the active layer are disposed on the buffer layer.

In some embodiments, the plurality of transistors include a plurality of drive transistors and a plurality of switch transistors, wherein the plurality of drive transistors includes a first drive transistor, and the plurality of switch transistors includes a first switch transistor; wherein

a width of the gate insulating layer of the first switch transistor in a first direction is greater than a width of the gate insulating layer of the first drive transistor in the first direction, wherein the first direction is an arrangement direction of the first electrode opening and the second electrode opening.

In some embodiments, a first distance between an edge of the gate insulating layer at the first electrode opening and the gate in a first direction is greater than a second distance between an edge of the gate insulating layer at the second electrode opening and the gate in the first direction, wherein the first direction is an arrangement direction of the first electrode opening and the second electrode opening.

In some embodiments, a width of the first electrode opening in a first direction is greater than a width of the second electrode opening in the first direction.

In some embodiments, the active layer includes a first end portion, a connection portion, and a second end portion, the connection portion being connected to the first end portion and the second end portion; wherein

an orthographic projection of the first end portion on the base is within the orthographic projection of the first electrode on the base, an orthographic projection of the second end portion on the base is within the orthographic projection of the second electrode on the base, and in a second direction, a width of at least one of the first end portion and the second end portion in the second direction is greater than a width of the connection portion in the second direction, wherein the second direction is a direction perpendicular to an arrangement direction of the first electrode opening and the second electrode opening.

In some embodiments, the second electrode covers an edge of the second electrode opening away from the gate, and there is a distance between the second electrode and an edge of the second electrode opening close to the gate.

In some embodiments, the transistor further includes a first conductive block; wherein the first conductive block is disposed on the base, the active layer is lapped on the first conductive block, and an orthographic projection of the first conductive block on the base overlaps with the first overlapping region.

In some embodiments, the second electrode covers the second electrode opening, and the orthographic projection of the second electrode opening on the base is within the orthographic projection of the second electrode on the base.

In some embodiments, the first conductive block and the first electrode are a same layer structure.

In some embodiments, the array substrate further includes: a buffer layer disposed between the active layer and the first electrode, wherein the buffer layer is provided with a buffer layer opening, and the partial region of the first electrode is exposed from the buffer layer opening;
the active layer covers the buffer layer opening and covers the partial region of the first electrode in the buffer layer opening;
the first insulating layer covers a climbing portion of the active layer, wherein the climbing portion of the active layer is a portion of the active layer that covers a hole wall of the buffer layer opening.

In some embodiments, the distance between the second electrode and the gate ranges from 2 μm to 3 μm.

In some embodiments, the transistor further includes a second conductive block; wherein the second conductive block and the first electrode are a same layer structure, and an orthographic projection of the second conductive block on the base overlaps with the first overlapping region.

In some embodiments, the transistor satisfies:

$$L + 2 * T \geq 7 ;$$

wherein L is equal to a width of the gate in a first direction, T is equal to a first distance between an edge of the gate insulating layer at the first electrode opening and the gate, and T is equal to a second distance between an edge of the gate insulating layer at the second electrode opening and the gate.

In some embodiments, a mobility of the active layer is greater than or equal to 20 square centimeters per volt per second.

In some embodiments, a material of the active layer includes an indium gallium zinc oxide, and a thickness of the active layer ranges from 300 angstroms to 500 angstroms.

According to another aspect of the present disclosure, a display panel is provided. The display panel includes the array substrate described in the above aspect.

According to still another aspect of the present disclosure, a method for manufacturing an array substrate is provided. The method includes:
acquiring a base;
manufacturing a plurality of transistors on the base, wherein the transistor includes:
a first electrode disposed on the base;
an active layer disposed on the base on which the first electrode is provided, wherein the active layer at least covers a partial region of the first electrode;
a first insulating layer disposed on a side of the active layer away from the base, wherein the first insulating layer is provided with a second electrode opening, wherein an orthographic projection of the second electrode opening on the base and an orthographic projection of the active layer on the base have a first overlapping region;
a gate disposed on a side of the first insulating layer away from the base, wherein the gate is disposed on the first insulating layer, and an orthographic projection of the gate on the base and the orthographic projection of the active layer on the base have a second overlapping region; and
a second electrode disposed on the side of the first insulating layer away from the base or disposed on a side of the first insulating layer close to the base;
wherein the orthographic projection of the second electrode opening on the base overlaps with an orthographic projection of the second electrode on the base, the second electrode is in contact with the active layer, and when the transistor operates, a voltage of the first electrode is greater than a voltage of the second electrode.

The technical solutions of the embodiments of the present disclosure can at least have the following beneficial effects.

The first electrode having the higher voltage in the first electrode and the second electrode of the transistor is disposed between the active layer and the base in a lower lap manner, and the second electrode having the lower voltage is disposed on the first insulating layer in an upper lap manner or disposed below the first insulating layer in the lower lap manner. When the second electrode is disposed in the upper lap manner, the conducting degree of the surface of the active layer away from the base is greater than the conducting degree of the surface of the active layer close to the base, which can reduce the resistance of the active layer in contact with the second electrode, thereby avoiding the problem that the transistor cannot operate normally due to the too large resistance at the second electrode. When the second electrode is disposed in the lower lap manner, the risk that the active layer is easily damaged at the via hole when the active layer is in contact with the electrode through the via hole can be avoided, thereby solving the problem of the poor performance of the array substrate in the related art, and improving the performance of the array substrate.

### BRIEF DESCRIPTION OF DRAWINGS

For a clearer description of the technical solutions in the embodiments of the present disclosure, the following briefly introduces the accompanying drawings required for describing the embodiments. The accompanying drawings in the following descriptions show merely some embodiments of the present disclosure, and persons of ordinary skill in the art may still derive other drawings from these accompanying drawings without creative effort.

FIG. 1 is a schematic structural diagram of an array substrate;

FIG. 2 is a schematic structural diagram of an array substrate according to some embodiments of the present disclosure;

FIG. 3 is a schematic structural diagram of another array substrate according to some embodiments of the present disclosure;

FIG. 4 is a schematic structural diagram of still another array substrate according to some embodiments of the present disclosure;

FIG. 5 is a schematic structural diagram of still another array substrate according to some embodiments of the present disclosure;

FIG. 6 is a schematic structural diagram of still another array substrate according to some embodiments of the present disclosure;

FIG. 7 is a top view of a structure of an array substrate according to some embodiments of the present disclosure;

FIG. 8 is a schematic diagram of a sectional structure of the array substrate shown in FIG. 7;

FIG. 9 is a top view of a structure of an array substrate according to some embodiments of the present disclosure;

FIG. 10 is a schematic diagram of a sectional structure of the array substrate shown in FIG. 9;

FIG. 11 is a top view of a structure of an array substrate according to some embodiments of the present disclosure;

FIG. 12 is a schematic diagram of a sectional structure of the array substrate shown in FIG. 11;

FIG. 13 is a top view of a structure of another array substrate according to some embodiments of the present disclosure;

FIG. 14 is a diagram showing a relationship between various parameters and a resistance at an electrode;

FIG. 15 is a schematic structural diagram of still another array substrate according to some embodiments of the present disclosure;

FIG. 16 is a diagram showing a relationship between parameters in a transistor;

FIG. 17 is a diagram showing a relationship between other parameters in a transistor; and

FIG. 18 is a flowchart of a method for manufacturing an array substrate according to some embodiments of the present disclosure

Specific embodiments of the present disclosure have been shown by means of the above accompanying drawings and will be described in more detail hereinafter. These accompanying drawings and textual descriptions are not intended to limit the scope of the concepts of the present disclosure in any way, but rather to illustrate the concepts of the present disclosure for those skilled in the art by reference to particular embodiments.

### DETAILED DESCRIPTION

To make the objectives, technical solutions and advantages of the present disclosure clearer, the embodiments of the present disclosure will be further described in detail below with reference to the accompanying drawings.

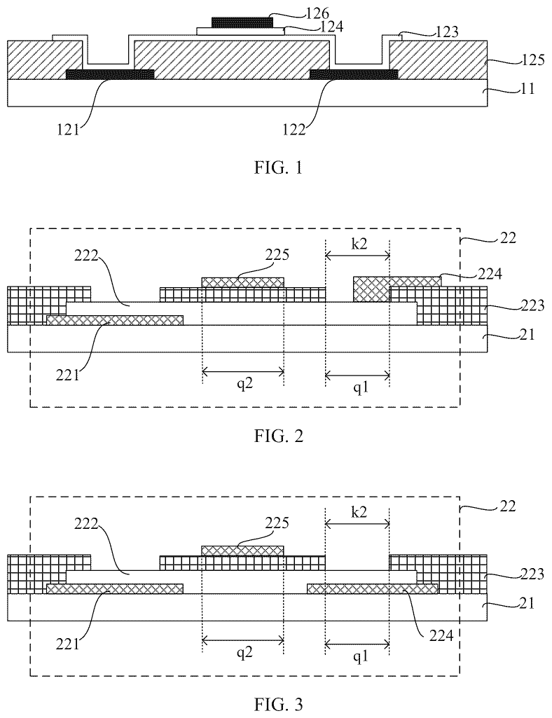

FIG. 1 is a schematic structural diagram of an array substrate. The array substrate includes a base 11 and a plurality of transistors 12 arranged in an array on the base 11. The transistor 12 includes a source 121 and a drain 122 disposed on the base 11, a buffer layer 125 covering the source 121 and the drain 122, an active layer 123 covering the buffer layer 125, a gate insulating layer 124 covering the active layer 123, and a gate 126 disposed on the gate insulating layer 124. The active layer 123 is in contact with the source 121 and the drain 122 through via holes in the buffer layer 125, and the gate 126 controls the active layer 123, so that the source 121 and the drain 122 are coupled through the active layer 123.

However, the source 121 and the drain 122 of the above transistor cannot be coupled under some situations. For example, when the transistor operates, the voltage at the drain 122 is lower than the voltage at the source 121, and the drain 122 is a low voltage terminal in the transistor. Thus, when the active layer 123 in contact with the drain 122 has a too large resistance, the drain 122 cannot be coupled. As a result, the transistor cannot be normally turned on and turned off, resulting in poor performance of the array substrate.

The embodiments of the present disclosure provide an array substrate, a display panel, and a method for manufacturing the array substrate, which can solve some problems in the related art.

FIG. 2 is a schematic structural diagram of an array substrate according to some embodiments of the present disclosure, and FIG. 3 is a schematic structural diagram of another array substrate according to some embodiments of the present disclosure. Referring to FIG. 2 and FIG. 3, the array substrate 20 includes a base 21 and a plurality of transistor 22 disposed on the base 21. The transistor 22 includes:
a first electrode 221 disposed on the base 21;
an active layer 222 disposed on the base 21 on which the first electrode 221 is provided, wherein the active layer 222 at least covers a partial region of the first electrode 221;
a first insulating layer 223 disposed on the side of the active layer 222 away from the base 21, wherein the first insulating layer 223 is provided with a second electrode opening k2, and an orthographic projection of the second electrode opening k2 on the base 21 overlaps with an orthographic projection of the active layer 222 on the base 21, that is, the active layer 222 is exposed from the second electrode opening k2;
a gate 225 disposed on the side of the first insulating layer 223 away from the base 21, wherein the second electrode 224 is in contact with the active layer 222 through the second electrode opening k2, the gate 225 is disposed on the first insulating layer 223, and an orthographic projection of the gate 225 on the base 21 and the orthographic projection of the active layer 222 on the base 21 have a second overlapping region q2;
a second electrode 224, wherein the second electrode 224 is disposed on the side of the first insulating layer 223 away from the base 21 (as shown in FIG. 2), or the second electrode 224 is disposed on the side of the first insulating layer 223 close to the base 21 (as shown in FIG. 4); an orthographic projection of the second electrode opening K2 on the base 21 overlaps with an orthographic projection of the second electrode 224 on the base 21, and the second electrode 224 is in contact with the active layer 222.

When the transistor 22 operates, the voltage of the first electrode 221 is greater than the voltage of the second electrode 224. That is, the first electrode 221 is a high voltage terminal of the transistor 22, and the second electrode 224 is a low voltage terminal of the transistor 22. For example, the first electrode 221 is a drain, and the second electrode 224 is a source.

In summary, according to the array substrate provided in the embodiments of the present disclosure, the first electrode having the higher voltage in the first electrode and the second electrode of the transistor is disposed between the active layer and the base in a lower lap manner, and the second electrode having the lower voltage is disposed on the first insulating layer in an upper lap manner or disposed below the first insulating layer in the lower lap manner. When the second electrode is disposed in the upper lap manner, the conducting degree of the surface of the active layer away from the base is greater than the conducting degree of the surface of the active layer close to the base, which can reduce the resistance of the active layer in contact with the second electrode, thereby avoiding the problem that the transistor cannot operate normally due to the too large resistance at the second electrode. When the second electrode is disposed in the lower lap manner, the risk that the active layer is easily damaged at the via hole when the active layer is in contact with the electrode through the via hole can be avoided, thereby solving the problem of the poor performance of the array substrate in the related art, and improving the performance of the array substrate.

A top-gate structure is a transistor structure in which the gate is disposed on the gate insulating layer and the active layer. In the development process of this technology, it has become a major research direction to simplify the patterning process and reduce costs at the current stage. For this, one patterning process is reduced and the source and drain metal can be arranged lower (the source and drain metal is disposed below the active layer) for the top-gate, bottom-contact (TGBC) structure compared to the conventional top-gate structure, so that various effects such as the reduction of the width of the data line and the reduction of the logic power consumption of the display panel can be achieved.

However, as shown in FIG. 1, in the current transistor having the top-gate, bottom-contact structure, the side of the active layer 123 close to the base 11 is lapped on the source 121 and the drain 122. Since the conducting process on the active layer 123 is performed from the side of the active layer 123 away from the base 11, and thus the conducting effect of the upper surface of the active layer 123 away from the base 11 is better than that of the lower surface of the active layer 123 close to the base 11. In such a structure, the active layer in contact with the source 121 and the drain 122 has a bigger lap resistance on the lower surface of the active layer close to the base 11.

Under this situation, at the drain 122, the electrons are conducted from the lower drain 122 to the upper active layer 123. Thus, the high voltage effect can be utilized such that the barrier on the lower surface of the active layer 123 having the poorer conducting effect can be broken through by the high voltage, and thus drain terminal is not affected. However, at the source 121 terminal, the electrons are conducted from the active layer 123 to the lower source 121, and the voltage at the source is lower than the voltage at the drain. Thus, the barrier at the source cannot be broken through, and it is difficult for the source to conduct electricity.

In the array substrate provided in the embodiments of the present disclosure, the high voltage terminal is lower lapped and the low voltage terminal is upper lapped, which can solve the above problem.

FIG. 4 is a schematic structural diagram of still another array substrate according to some embodiments of the present disclosure. The first insulating layer 223 is further provided with a first electrode opening k1. An orthographic projection of the first electrode opening k1 on the base 21 and an orthographic projection of the active layer 222 on the base 21 have a third overlapping region q3, and the third overlapping region q3 overlaps with the first electrode 221.

The first insulating layer 223 includes a gate insulating layer gi disposed between the first electrode opening k1 and the second electrode opening k2, and an orthographic projection of the edge s1, covered by the active layer 222, of the first electrode 221 on the base 21 is within an orthographic projection of the gate insulating layer gi on the base 21. In the array substrate 20, the portion of the active layer 222 which covers the edge s1 of the first electrode 221 (this portion is considered as the portion of the active layer which is above the edge s1) is thinner than the remaining portion of the active layer 222 due to a segment difference at the edge of the first electrode 221, and this portion may be damaged in subsequent processes. For example, the first electrode opening k1 and the second electrode opening k2 are formed in the process of manufacturing the first insulating layer 223, and if this portion is disposed at the first electrode opening k1 or the second electrode opening k2, this portion may be damaged due to the influence of the etching process, which results in a lapping abnormality of the active layer 222 and the first electrode 221 or the second electrode 224, thereby affecting the performance of the array substrate 20.

In the array substrate 20 provided in the embodiments of the present disclosure, the gate insulating layer gi covers the portion of the active layer 222 which covers the edge of the first electrode 221, such that this portion is protected and is prevented from being damaged in subsequent processes. In addition, the gate insulating layer gi in the present disclosure is manufactured at the same time when the first insulating layer 223 is manufactured, without the need to perform the patterning process on the self-aligned gate insulating layer gi, thereby saving the patterning process.

It should be noted that, the conducting degree of the surface of the active layer 222 away from the base 21 (the upper surface of the active layer in FIG. 4) may be improved under the influence of some upper film layers (not shown in FIG. 4), and on the other hand, the conducting process may also be performed from the side of the active layer away from the base 21, such that the conducting degree of the surface of the active layer 222 away from the base 21 is greater than the conducting degree of the surface of the active layer 222 close to the base 21 (the lower surface of the active layer in FIG. 4).

On this basis, although that the gate insulating layer gi covers the portion of the active layer 222 which covers the edge s1 of the first electrode 221 affects the conducting effect of the active layer 222, in the array substrate 20 provided in the embodiments of the present disclosure, the second electrode 224 is disposed in the upper lapping manner such that the second electrode 224 is in contact with the surface of the active layer 222 away from the base 21 which has a greater conducting degree, thereby ensuring the performance of the transistor 22.

The length L1 in a first direction f1 of the overlapping region between the orthographic projection of the gate insulating layer gi on the base 21 and the orthographic projection of the first electrode 221 on the base 21 is greater than or equal to 1 μm, which can avoid the situation that the gate insulating layer gi does not cover the portion of the active layer 222 which covers the edge of the first electrode 221 due to the process error. The first direction f1 is an arrangement direction of the first electrode opening k1 and the second opening k2. The first direction f1 is parallel to an extension direction of a channel of the transistor 22. The channel is a conductive layer formed due to an applied electric field (which is applied by the gate 225) in the active layer, and the conductive layer is configured to couple the first electrode 221 and the second electrode 224.

Additionally, the transistors in the embodiments of the present disclosure are thin film transistors.

In an example embodiment, the first distance h1 between the edge s2 of the gate insulating layer gi at the first electrode opening k1 and the gate 225 in the first direction f1 is positively correlated with the mobility of the active layer 222; and the second distance h2 between the edge s3 of the gate insulating layer gi at the second electrode opening k2 and the gate 225 in the first direction f1 is positively correlated with the mobility of the active layer 222. That is, the larger the refractive index of the active layer 222, the bigger the first distance h1 and the second distance h2; and the smaller the refractive index of the active layer 222, the smaller the first distance h1 and the second distance h2. That is, in the array substrate 20 provided in the embodiments of the present disclosure, the first distance h1 and the second distance h2 can be adjusted based on the mobility of the active layer 222. When the first distance h1 and the second distance h2 are too large, the area of the portion of the active layer 222 which is exposed at the first insulating layer 223 is reduced, which further affects the conducting degree of the active layer 222. Therefore, the mobility of the active layer 222 is associated with the first distance h1 and the second distance h2, and it is made that the mobility of the active layer 222 is positively correlated with the first distance h1 and the second distance h2. In an example embodiment, the first distance h1 ranges from 2 μm to 4 μm, and the second distance h2 ranges from 2 μm to 4 μm. Under this distance ranges, the gate insulating layer gi can be prevented from seriously affecting the conducting of the active layer.

In addition, the first distance h1 and the second distance h2 may be equal or unequal, which is not limited in the embodiments of the present disclosure.

It should be noted that the portion of the gate insulating layer gi which is disposed between the edge s2 at the first electrode opening k1 and the gate 225 and the portion of the gate insulating layer gi which is disposed between the edge s3 at the second electrode opening k2 and the gate 225 are referred to as gate insulating layer tails (GI tail) on two sides of the gate 225, respectively.

In the array substrate 20 provided in the embodiments of the present disclosure, the mobility of the active layer 222 depends on the material of the active layer. In some embodiments, the material of the active layer includes a high mobility oxide, and the mobility is greater than or equal to 20 square centimeters per volt per second (cm²V⁻¹s⁻¹), or the mobility is greater than or equal to 30 square centimeters per volt per second, which is not limited in the embodiments of the present disclosure. In an example embodiment, the material of the active layer includes indium gallium zinc oxide (IGZO) doped with other elements (such as a lanthanum (Ln) element), or the active layer is an IGZO film layer formed by an atomic layer deposition (ALD) device. The thickness of the active layer 222 ranges from 300 Å to 500 Å.

It should be noted that, at present, in the process of manufacturing a transistor (such as a transistor having a top-gate, bottom-contact (TGBC) structure), an etching opening of a large area is formed in the insulating layer on the active layer to increase the area of the exposed active layer, and then a conducting process is performed on the active layer exposed from the opening in the insulating layer. In the transistor manufactured by this manufacturing process, the active layer exposed from the opening in the insulating layer has a larger size, and the size of the active layer also increases. Thus, the overall size of the transistor is too large, which is not conducive to increasing the density of the transistors in the array substrate, and further reducing the pixel density of the display panel adopting the array substrate.

In the array substrate provided in the embodiments of the present disclosure, by using the high mobility oxide with a mobility greater than or equal to 20 cm²V⁻¹s⁻¹ as the material of the active layer, and according to the arrangement of the gate insulating layer tails in the foregoing embodiment and the upper lapping scheme of the second electrode, the performance of the transistor is improved. Furthermore, in the manufacturing process, the position of the channel and the gate insulating layer tails can be defined through the first electrode opening and the second electrode opening, such that the size of the active layer can be reduced, and the density of the transistors in the array substrate can be increased, thereby increasing the pixel density of the display panel adopting the array substrate.

Referring to the transistor of the array substrate shown in FIG. 4, the second electrode 224 covers the edge s4 of the second electrode opening k2 away from the gate 225, and there is a distance between the second electrode 224 and the edge of the second electrode opening k2 close to the gate 225 (this edge is the edge s3 of the gate insulating layer gi at the second electrode opening k2).

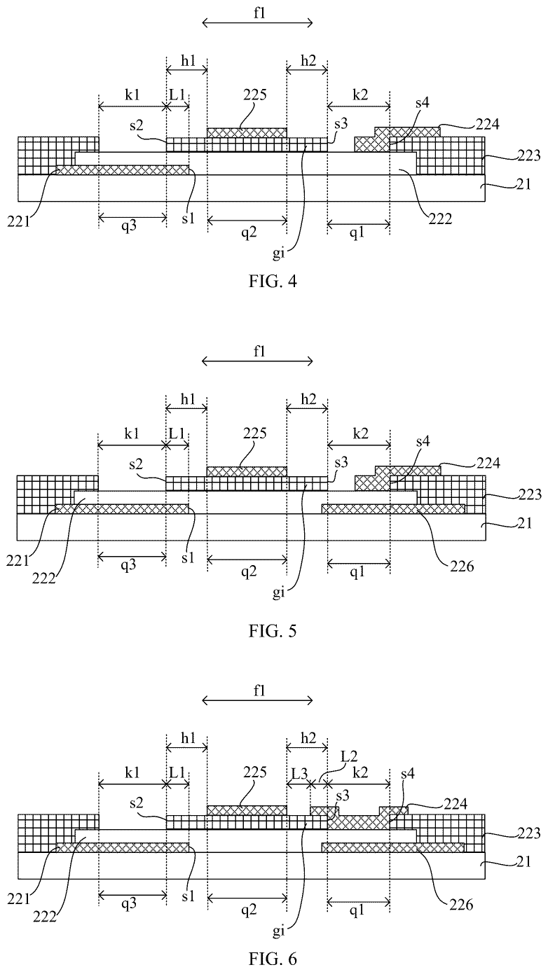

For the transistor shown in FIG. 4, in the manufacturing process of a transistor, the gate 225 and the second electrode 224 are formed in a single patterning process, and the etching in this patterning process is wet etching. Since the critical dimension bias (CD Bias) of the wet etching is large (the critical dimension bias refers to the difference between the size of the patterned photoresist and the size of the pattern under the photoresist after the etching is completed), the conducting degree of a portion of the active layer is reduced, thereby causing the resistance of the low-voltage terminal where the second electrode 224 is disposed to increase, which affects the electrical properties of the transistor. For this, please refer to FIG. 5, and FIG. 5 is a schematic structural diagram of still another array substrate according to some embodiments of the present disclosure. There are some adjustments to the transistor in the array substrate 20 on the basis of the transistor shown in FIG. 4, and the transistor further includes a first conductive block 226. The first conductive block 226 is disposed on the base 21, the active layer 222 is lapped on the first conductive block 226, and an orthographic projection of the first conductive block 226 on the base 21 overlaps with the first overlapping region q1. That is, the first conductive block 226 and the second electrode 224 are respectively disposed on two sides of the portion of the active layer 222 which is exposed from the second electrode opening k2, thereby forming a structure sandwiching the active layer 222. With such a structure, there is a voltage difference between the first conductive block 226 and the second electrode 224, and the first conductive block 226 can sense a voltage, and this voltage can act on the active layer 222 to reduce the resistance of the low voltage terminal where the second electrode 224 is disposed. In addition, the first conductive block 226 is in contact with the active layer 222, and there is a density difference between the first conductive block 226 and the active layer 222, which can enhance the conducting effect of the active layer 222, and reduce the resistance of the low voltage terminal where the second electrode 224 is disposed to avoid that the low voltage terminal cannot be coupled, thereby improving the electrical properties of the transistor.

The first conductive block 226 and the first electrode 221 are a same layer structure. The first conductive block 226 and the first electrode 221 may be made of the same material, such that the first conductive block 226 and the first electrode 221 can be formed by a single patterning process. The first conductive block 226 and the first electrode 221 each include a metal material.

The patterning process in the embodiments of the present disclosure includes steps of coating photoresist, exposure, developing, etching, and photoresist stripping.

FIG. 6 is a schematic structural diagram of still another array substrate according to some embodiments of the present disclosure, and some adjustments are made to transistor in FIG. 6 on the basis of the transistor shown in FIG. 5. Referring to FIG. 6, the second electrode 224 covers the second electrode opening k2, and the orthographic projection of the second electrode opening k2 on the base 21 is within the orthographic projection of the second electrode 224 on the base 21. In this structure, the second electrode 224 covers the entire second electrode opening k2.

The distance L2 of the portion, covered by the second electrode 224, of the gate insulating layer gi in the first direction f1 ranges from 1 μm to 2 μm, so as to avoid that the second electrode 224 cannot cover second electrode opening k2 due to process errors. The distance L3 between the gate 225 and the second electrode 224 in the first direction f1 ranges from 2 μm to 3 μm, for example, 2.5 μm, so as to reduce the distance between the second electrode 224 and the gate 225, thereby reducing the overall size of the transistor and further increasing the pixel density (pixels per inch, PPI) of the display panel adopting the array substrate.

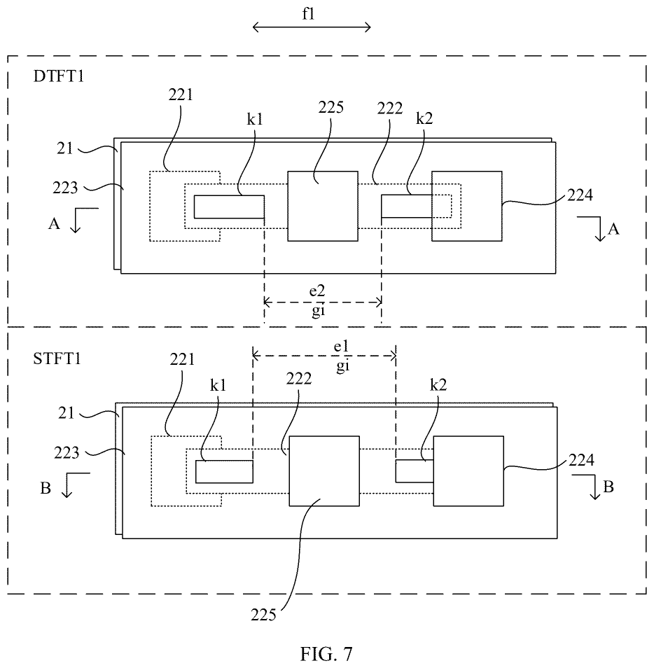

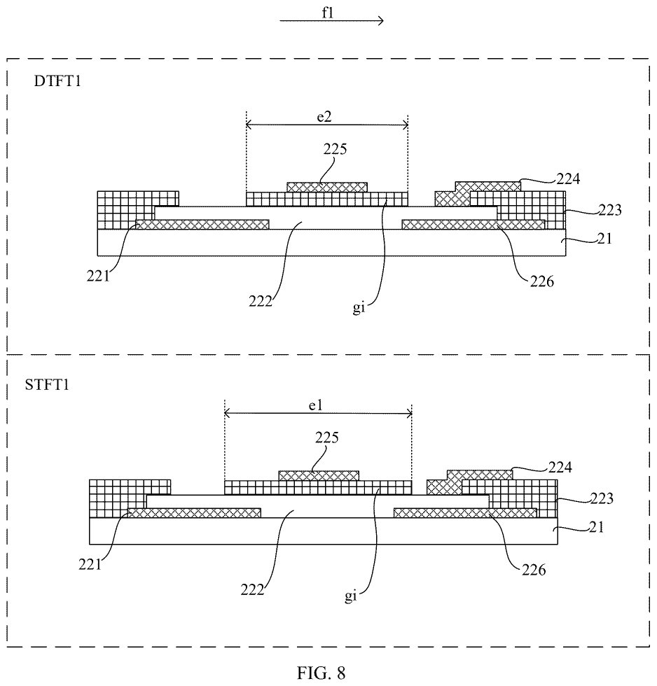

It should be noted that, for different types of transistors in the array substrate in the related art, the gate insulating layer tails (GI Tail) have the same size. However, the requirement on the size of the gate insulating layer tail may be different for different types of transistors. Therefore, the performance of the array substrate in the related art is poor. Based on this, please refer to FIG. 7, and FIG. 7 is a top view of a structure of an array substrate according to some embodiments of the present disclosure (FIG. 7 shows the top views of the structures of two transistors at two positions). FIG. 8 is a schematic diagram of a sectional structure of the array substrate shown in FIG. 7 (FIG. 8 shows the schematic diagrams of the sectional structures of two transistors at two positions corresponding to FIG. 7, the sectional position of STFT1 is A-A, and the sectional position of DTFT1 is B-B). Referring to FIG. 7 and FIG. 8, the plurality of transistors 22 in an array substrate 20 according to the embodiments of the present disclosure include a plurality of drive transistors (DTFT) and a plurality of switch transistors (STFT). The plurality of drive transistors DTFT includes a first drive transistor DTFT1, and the plurality of switch transistors STFT includes a first switch transistor STFT1.

The width e1 of the gate insulating layer gi of the first switch transistor STFT1 in the first direction f1 is greater than the width e2 of the gate insulating layer gi of the first drive transistor DTFT1 in the first direction f1. Similar to the foregoing embodiments, the first direction f1 is an arrangement direction of the first electrode opening k1 and the second opening k2. That is, in this structure, the width e1 of the gate insulating layer gi of at least one switch transistor STFT in the array substrate in the first direction f1 is greater than the width e2 of the gate insulating layer gi of one drive transistor DTFT in the first direction f1, that is, in different types of transistors, in the case that the widths of the gates 225 in the first direction f1 are the same or different, the width of the gate insulating layer tail (GI Tail) of the switch transistor STFT in the first direction f1 is greater than the width of the gate insulating layer tail (GI Tail) of the drive transistor DTFT in the first direction f1.

Certainly, it may also be that the width of the gate insulating layer gi of each switch transistor STFT in the array substrate 20 in the first direction f1 is greater than the width of the gate insulating layer gi of each drive transistor DTFT in the first direction f1, which is not limited in the embodiments of the present disclosure.

Since the channel of the switch transistor is usually shorter, in the present disclosure, after the width of the gate insulating layer tail (GI Tail) of the switch transistor STFT in the first direction f1 is increased, the problem that the effective channel of the switch transistor is too short due to the influence of the manufacturing process can be avoided, and the product yield is improved. In addition, since the channel of the drive transistor DTFT is usually longer, after the width of the gate insulating layer tail (GI Tail) in the first direction f1 is reduced, the influence caused thereby is also small. Therefore, in the present disclosure, the overall size of the drive transistor DTFT can be reduced after the width of the gate insulating layer tail (GI Tail) of the drive transistor DTFT in the first direction f1 is reduced.

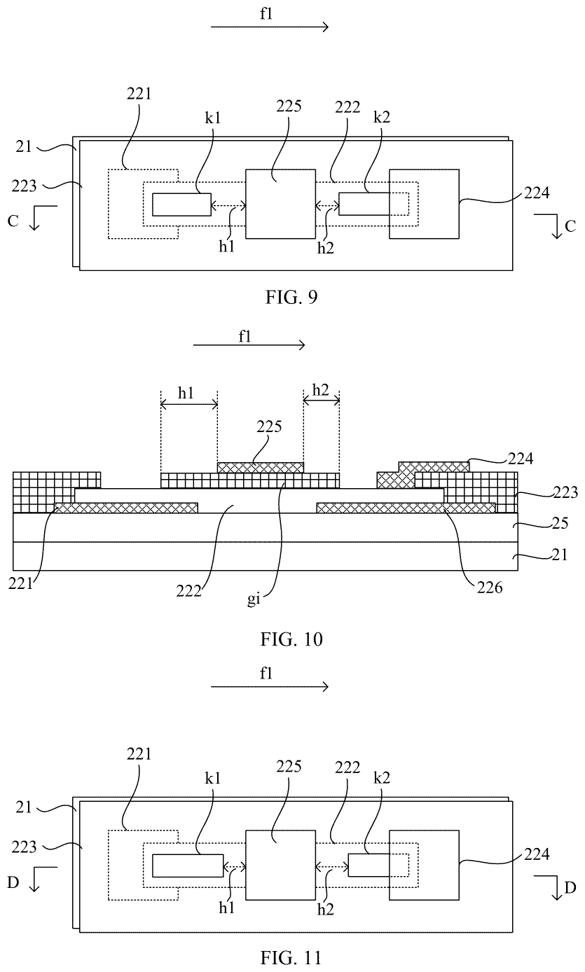

In an example embodiment, referring to FIG. 9 and FIG. 10, FIG. 9 is a top view of an array substrate according to some embodiments of the present disclosure, and FIG. 10 is a schematic diagram of a sectional structure of the array substrate shown in FIG. 9 (FIG. 10 is a schematic diagram of a sectional structure at C-C of the array substrate shown in FIG. 9). The first distance h1 between the edge s2 of the gate insulating layer gi at the first electrode opening k1 and the gate 225 in the first direction f1 is greater than the second distance h2 between the edge s3 of the gate insulating layer gi at the second electrode opening k2 and the gate 225 in the first direction f1, and the first direction f1 is the arrangement direction of the first electrode opening k1 and the second electrode opening k2. In this structure, the size of the gate insulating layer tail (GI Tail) of the transistor at the first electrode 221 (high voltage terminal) is greater than the size of the gate insulating layer tail (GI Tail) of the transistor at the second electrode 224 (the low voltage terminal), such that the influence of the first electrode 221 (high voltage terminal) on the channel of the transistor can be reduced, and the electrical properties such as the voltage resistance of the transistor can be ensured.

In the related art, the sizes of the gate insulating layer tails (GI Tail) at the source and the drain in the transistor are the same. In the transistor provided in the embodiments of the present disclosure, the size of the gate insulating layer tail at the first electrode 221 (high voltage terminal) is increased, or the size of the gate insulating layer tail at the second electrode 224 (low voltage terminal) is reduced, so as to improve the electrical properties such as the voltage resistance of the transistor. This structure can be applicable to one or more transistors in the array substrate provided in the embodiments of the present disclosure, and can also be applicable to at least one of the switch transistor STFT and the drive transistor DTFT, which is not limited in the embodiments of the present disclosure.

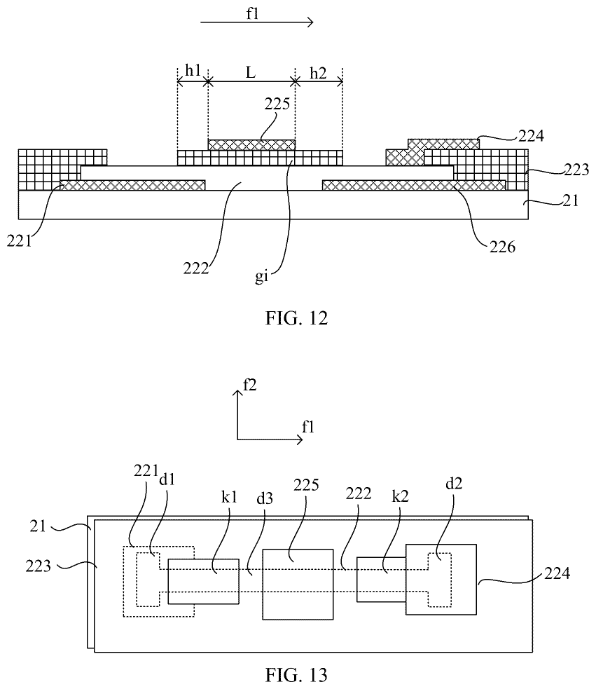

In an example embodiment, referring to FIG. 11 and FIG. 12, FIG. 11 is a top view of a structure of an array substrate according to some embodiments of the present disclosure, and FIG. 12 is a schematic diagram of a sectional structure of the array substrate shown in FIG. 11 (FIG. 12 is a schematic diagram of a sectional structure at D-D of the array substrate shown in FIG. 11). The width of the first electrode opening k1 in the first direction f1 is greater than the width of the second electrode opening k2 in the first direction f1. That is, in this transistor, the first insulating layer 223 is provided with a first electrode opening k1 which is provided at the first electrode 221 (high voltage terminal) and a second electrode opening k2 which is provided at the second electrode 224 (low voltage terminal), the active layer 222 is exposed from the two openings, and the width of the first electrode opening k1 in the first direction f1 is greater than the width of the second electrode opening k2 in the first direction f1. In this structure, the area of the active layer 222 exposed at the high voltage terminal is greater than the area of the active layer 222 exposed at the low voltage terminal, such that the high voltage terminal acts on the active layer path having a greater resistance, thereby achieving the effect of voltage division, and improving the voltage resistance of the transistor. The structures shown in FIG. 11 and FIG. 12 can be applicable to one or more transistors in the array substrate provided in the embodiments of the present disclosure, for example, transistors having a high voltage resistance requirement in the array substrate.

In an example embodiment, referring to FIG. 13, FIG. 13 is a top view of another array substrate according to some embodiments of the present disclosure (the viewing line of sight is perpendicular to the base). The active layer 222 includes a first end portion d1, a connection portion d3, and a second end portion d2. The connection portion d3 is connected to the first end portion d1 and the second end portion d2.

The orthographic projection of the first end portion d1 on the base 21 is within the orthographic projection of the first electrode 221 on the base 21, and the orthographic projection of the second end portion d2 on the base 21 is within the orthographic projection of the second electrode 224 on the base 21. In the second direction f2, the width of at least one of the first end portion d1 and the second end portion d2 in the second direction is greater than the width of the connection portion in the second direction, and the second direction f2 is a direction perpendicular to the arrangement direction (i.e., the first direction f1) of the first electrode opening k1 and the second electrode opening k2. The second direction f2 may be a direction perpendicular to an extension direction of the channel of the transistor.

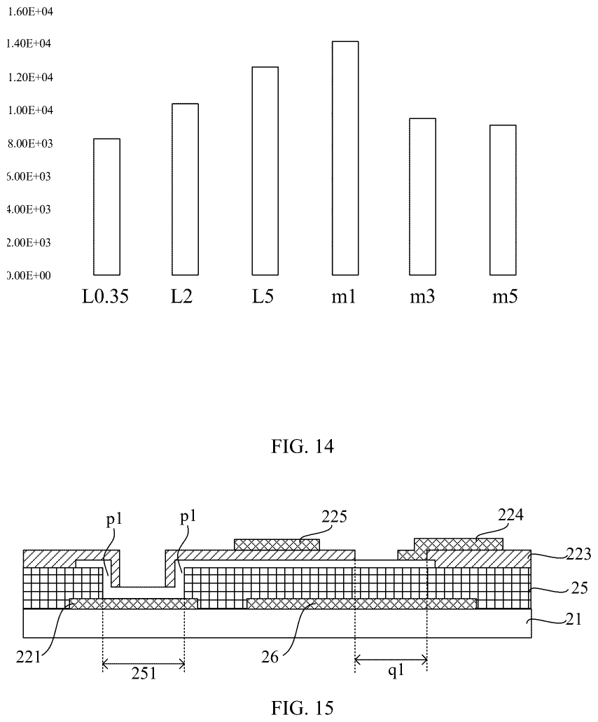

Referring to FIG. 14, FIG. 14 is a diagram showing a relationship between a distance and a resistance at an electrode (the resistance may be a resistance at an electrode which is lapped on the active layer). The horizontal coordinate L0.35 indicates that the size of the active layer exposed in the first direction is 0.35 μm, the horizontal coordinate L2 indicates that the size of the active layer exposed in the first direction is 2 μm, the horizontal coordinate L5 indicates that the size of the active layer exposed in the first direction is 5 μm, m1 indicates the lapping distance between the active layer and the electrode (the distance may be a lapping distance between the active layer and the electrode in the first direction) is 1 μm, m3 indicates that the lapping distance between the active layer and the electrode is 3 μm, and m5 indicates that the lapping distance between the active layer and the electrode is 5 μm. The vertical coordinate represents the resistance, in the unit of ohm. It can be seen that the smaller the size of the active layer exposed in the first direction (the smaller the distance between the exposed active layer and the channel), the smaller the resistance; and the larger the lapping area between the active layer and the electrode, the smaller the resistance.

Referring to FIG. 13 and FIG. 14, by setting the connection portion d3 of the active layer 222 between the first electrode 221 and the second electrode 224 to have a smaller width (the width in the second direction), and setting the first end portion d1 and the second end portion d2 of the active layer 222 which is lapped on the first electrode 221 and second electrode 224 to have larger widths (widths in the second direction), the resistance of the transistor at the first electrode and the second electrode can be further reduced, thereby improving the electrical properties of the transistor.

Additionally, referring to FIG. 1, in the related art, after the source 121 and the drain 122 are formed, a buffer layer 125 is firstly formed, a via hole is then formed in the buffer layer 125, and then an active layer 123 is formed on the buffer layer 125. The active layer 123 is in contact with the source 121 and the drain 122 through the via hole in the buffer layer 125. In this structure, the active layer 123 has a climbing portion 1231 covering the hole wall of the via hole in the buffer layer 125, and under the influence of the segment difference at the via hole, the thickness of the climbing portion 1231 is smaller than the thickness of the active layer 123 at other positions. Thus, the climbing portion 1231 is easily damaged and poor in electrical conductivity.

In the array substrate provided in the embodiments of the present disclosure, referring to FIG. 10, the array substrate further includes a buffer layer 25 disposed between the first electrode 221 and the base 21, and the first electrode 221 and the active layer 222 are both disposed on the buffer layer 25. That is, in the array substrate, the active layer 222 is disposed after the first electrode 221 is disposed, such that the active layer 222 is directly lapped on the first electrode 221, without passing through the via hole in the buffer layer and other film layers. In this structure, the flatness at the position where the active layer 222 is lapped on the first electrode 221 is improved, and there is no climbing portion in the via hole lapping structure, thereby reducing the resistance abnormality and the possibility of breakage of the active layer.

In the transistor shown in FIG. 1, since there are via holes in the buffer layer, the number of the via holes in the transistor is greatly increased. The via holes occupy the space in the array substrate and limit the size of the transistor, which greatly increases the difficulty of reducing the size of the transistor, and thus it is difficult for the transistor to be applied to a display panel with a high pixel density. Meanwhile, the increase of the pixel density of the display panel is also limited.

In some organic light-emitting diode display panels with a high pixel density, since the display panels include internal compensation circuits including transistors, the number of the transistors is larger, and this problem is more serious.

In the array substrate provided in the embodiments of the present disclosure, the active layer 222 is directly lapped on the first electrode 221, without passing through the via hole in the film layers such as the buffer layer, which reduces the number of the via holes in the transistor, thereby reducing the limitation of the via holes on the size of the transistor. Therefore, the array substrate including the transistor does not affect the pixel density of the display panel, and the array substrate is applicable to display panels with a higher pixel density.

FIG. 15 is a schematic structural diagram of still another array substrate according to some embodiments of the present disclosure. The array substrate 20 further includes a buffer layer 25.

The buffer layer 25 is disposed between the active layer 222 and the first electrode 221, the buffer layer 25 is provided with a buffer layer opening 251, and a partial region of the first electrode 221 is exposed from the buffer layer opening 251. The active layer 222 covers the buffer layer opening 251 and covers the partial region of the first electrode 221 which is in the buffer layer opening 251.

The first insulating layer 223 covers a climbing portion p1 of the active layer 222, and the climbing portion p1 of the active layer 222 is a portion of the active layer 222 that covers the hole wall of the buffer layer opening 251.

This solution relates to another lower lapping structure at the high voltage terminal of the transistor where the first electrode 221 is disposed. Different from the above transistors, in this transistor, after the first electrode 221 is formed, the buffer layer 25 is first formed, and then the active layer 222 is formed. The active layer 222 is in contact with the first electrode 221 through the buffer layer opening 251 in the buffer layer 25. In this structure, the active layer forms a concave structure at the buffer layer opening 251, and the concave structure includes a portion of the active layer that covers the hole wall of the buffer layer opening 251. This portion of the active layer is the climbing portion p1 of the active layer 222. Due to the large segment difference of the region covered by the climbing portion p1 (the segment difference at the buffer layer opening 251 is large), the thickness of the climbing portion p1 is less than the thickness of the portion of the active layer that covers the buffer layer 25. Thus, in the array substrate shown in FIG. 1, the climbing portion p1 is disposed in the opening of the upper insulating layer, and is damaged by some processes for forming the opening. For example, the active layer is affected by the etching process to result in a poor conducting degree or even breakage, thereby reducing the electrical properties of the transistor. However, in the array substrate provided in the embodiments of the present disclosure, the first insulating layer 223 covers the climbing portion p1 of the active layer 222, and thus the probability that the climbing portion p1 of the active layer is damaged or even breaks caused by the processes such as the wet etching is reduced, thereby improving reliability and electrical properties of the transistor.

Furthermore, the transistor further includes a second conductive block 26. The second conductive block 26 and the first electrode 221 are a same layer structure, and an orthographic projection of the second conductive block 26 on the base overlaps with the first overlapping region q1. The function of the second conductive block 26 may be similar to that of the first conductive block in the array substrate provided in the above embodiments, that is, the second conductive block 26 and the second electrode 224 are respectively disposed on the side of the portion, exposed from the second electrode opening k2, of the active layer 222 and the side of the portion, exposed from the second electrode opening k2, of the buffer layer 25, to form a structure sandwiching the active layer 222 and a structure sandwiching the buffer layer 25. In this structure, there is a voltage difference between the conductive block 26 and the second electrode 224 such that the conductive block 26 can sense a voltage, and the voltage acts on the active layer 222, thereby reducing the resistance of the low voltage terminal where the second electrode 224 is disposed, reducing the possibility that the low voltage terminal cannot be coupled, and improving the electrical properties of the transistor.

The second conductive block 26 and the first electrode 221 are a same layer structure. The second conductive block 26 and the first electrode 221 are made of the same material, such that the second conductive block 26 and the first electrode 221 can be formed by a single patterning process. The second conductive block 26 and the first electrode 221 each include a metal material.

Additionally, the second conductive block 26 is not connected to other lines in the array substrate 20, so as to adopt a floating-like conductive structure, which can prevent the second conductive block 26 from being affected by the voltages on other lines, thereby preventing from adversely affecting the transistor.

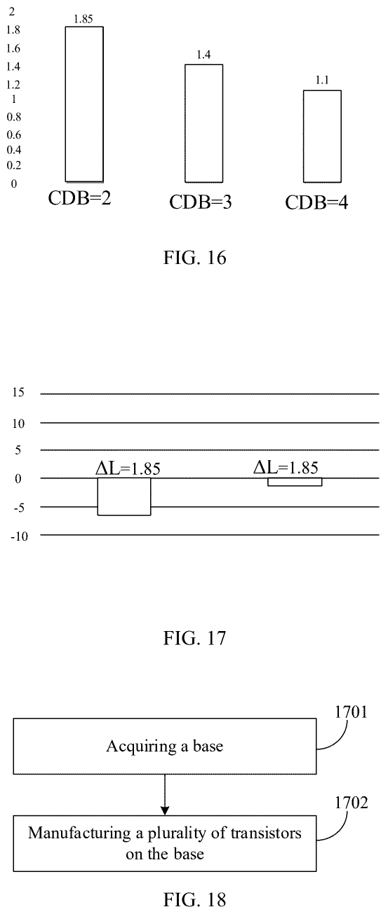

FIG. 16 is a diagram showing a relationship between parameters in a transistor, and FIG. 16 shows a relationship between a critical dimension bias (CDB) in an etching process for forming a gate and ΔL (the vertical axis in FIG. 16 represents ΔL). Referring to FIG. 1 and FIG. 16, ΔL is the size in the first direction f1 of a region, affected by the conducting process, of the channel of the active layer. When a conducting process is performed on the portion of the active layer that is exposed from the first insulating layer, the active layer below the gate is affected due to the critical dimension bias, thereby affecting the electrical properties of the transistor.

As can be seen from FIG. 16, the larger the critical dimension, the smaller the ΔL.

FIG. 17 is a diagram showing a relationship between other parameters in a transistor, and FIG. 17 shows a relationship between a threshold voltage Vth and ΔL of a transistor (the vertical coordinate represents Vth, in unit of volt). It can be seen that when ΔL becomes smaller, the absolute value of the negative bias of the threshold voltage Vth of the transistor becomes smaller accordingly. When the absolute value of the negative bias is too big, various display abnormalities such as brightness abnormality may be caused. On the basis of the contents shown in FIG. 16 and FIG. 17, referring to FIG. 12, in the array substrate provided in the embodiments of the present disclosure, the transistor satisfies:

$$L + 2 * T \geq 7 ;$$

wherein L is the size of the channel in the first direction f1, and L is equal to the width of the gate 225 in the first direction f1, T is equal to the first distance h1 between the edge s2 of the gate insulating layer gi at the first electrode opening k1 and the gate 225, and T is equal to the second distance h2 between the edge of the gate insulating layer gi at the second electrode opening k2 and the gate 225. In the transistor having this structure, the two gate insulating layer tails on two sides of the gate 225 have the same the size (the size in the first direction f1). In addition, in an example embodiment, on the basis of L+2*T≥7, the critical dimension in the etching process for forming the gate is 4 μm, T is 2 μm, ΔL is 1 μm, and the size L of the channel is 4 μm, thereby achieving the short channel of the transistor. If the size L is to be further reduced, the critical dimension bias can continue to be increased to reduce ΔL, thereby reducing the size L of the channel.

After tests, under such settings, ΔL of the transistor can be reduced, and thus the absolute value of the negative bias of the threshold voltage Vth of the transistor can be reduced, thereby improving the electrical properties of the transistor.

In an example embodiment, L+2*T≥8, and correspondingly, in one transistor, L is 5 μm, and T is greater than or equal to 1.5 μm; in another transistor, L is 4 μm, and T is greater than or equal to 1.5 μm; and in still another transistor, L is 3.5 μm, and T is greater than or equal to 2.25 μm. The array substrate provided in the embodiments of the present disclosure includes at least one of these transistors, such that the array substrate includes transistors having channels of different sizes.

The contents of the parameters such as L and T provided in the embodiments of the present disclosure are applicable to one or more array substrates provided in the foregoing embodiments.

Additionally, please refer to table 1 for some examples of critical dimensions and critical dimension biases in the wet etching processes.

TABLE 1

| | | |
|---|---|---|
| Serial number | FICD | CD bias |

| | | | |
|---|---|---|---|
| 1 | 6.1 | μm | 2 μm |
| 2 | 5.1 | μm | 3 μm |
| 3 | 3.85 | μm | 4 μm |

Designed values: CD = 8 μm, DICD = 8.1 μm

It can be seen from table 1 that in the case that the critical dimension (CD) is set to be 8 μm, and the critical dimension (DICD) of the photoresist after development is 8.1 μm, the critical dimension bias (CD bias) is different when the critical dimension (FICD) of the etched pattern is different. For example, when the critical dimension (FICD) of the etched pattern is 6.1 μm, the critical dimension bias is 2 μm; and when the critical dimension of the etched pattern is 5.1 μm, the critical dimension bias is 3 μm. Therefore, the critical dimension bias can be controlled by adjusting the critical dimension (FICD) of the etched pattern, and the critical dimension of the etched pattern can be achieved by adjusting the time parameter of the wet etching process.

Some embodiments of the present disclosure further provide a display panel, including any one of the array substrates provided by the above embodiments. The display panel further includes a display structure 30 disposed on the array substrate 11, and the array substrate 20 is configured to control the display structure 30. For different types of display panels, the display structures 30 are also different. For example, when the display panel is a self-illuminating display panel, the display structure 30 includes a plurality of light-emitting units 31, and the light-emitting unit 31 includes an organic light-emitting diode (OLED). The display structure 30 includes organic light-emitting diodes of a plurality of colors, for example, a red organic light-emitting diode for emitting red light, a green organic light-emitting diode for emitting green light, a blue organic light-emitting diode for emitting blue light, and the like. The circuit structure in the array substrate 20 is electrically connected to the organic light-emitting diode to drive the organic light-emitting diode to emit light, thereby achieving a display function.

In addition, the display structure 30 further includes a color film layer, and the color film layer is disposed on the side of the light-emitting unit 31 away from the array substrate. The color film layer can improve the color purity of the light emitted by the organic light-emitting diode and improve the display effect of the display panel.

Certainly, in another example embodiment, the display structure 30 includes a color film layer and a plurality of white light-emitting diodes for emitting white light, and the color film layer is disposed on the side of the white light-emitting diodes away from the array substrate.

In an example embodiment, the display panel is a liquid crystal display panel, and correspondingly, the display structure includes a liquid crystal layer and a color film layer. The liquid crystal layer is disposed on the array substrate 20, the array substrate 20 is configured to apply a voltage to the liquid crystal layer to control the liquid crystal layer, and the color film layer is disposed on the side of the liquid crystal layer away from the array substrate. When the display panel is a liquid crystal display panel, the display panel cooperates with a backlight assembly to achieve a display function. For example, the backlight assembly is disposed on the side of the array substrate 20 away from the liquid crystal layer, and the backlight source emits light which passes through the array substrate and irradiates the liquid crystal layer. The array substrate controls at least a partial region of the liquid crystal layer to transmit light and the other regions not to transmit light, and thus the light emitted by the backlight assembly can pass through the light-transmissive region and irradiate the color filter substrate, and then pass through the color filter substrate, thereby achieving the display function.

According to the array substrate provided in the embodiments of the present disclosure, the electrical properties of the transistor is improved, such that the transistors can also have good electrical properties when the transistors are arranged in a high density, which avoids the problem in the related art that the yield of the display panel is greatly reduced in the case that the pixel density is high. Thus, the manufacturing yield of the display panel in the case that the pixel density is high can be improved, and the display effect of the display panel can also be improved.

In summary, according to the array substrate provided in the embodiments of the present disclosure, the first electrode having the higher voltage in the first electrode and the second electrode of the transistor is disposed between the active layer and the base in a lower lap manner, and the second electrode having the lower voltage is disposed on the first insulating layer in an upper lap manner or disposed below the first insulating layer in the lower lap manner. When the second electrode is disposed in the upper lap manner, the conducting degree of the surface of the active layer away from the base is greater than the conducting degree of the surface of the active layer close to the base, which can reduce the resistance of the active layer in contact with the second electrode, thereby avoiding the problem that the transistor cannot operate normally due to the too large resistance at the second electrode. When the second electrode is disposed in the lower lap manner, the risk that the active layer is easily damaged at the via hole when the active layer is in contact with the electrode through the via hole can be avoided, thereby solving the problem of the poor performance of the array substrate in the related art, and improving the performance of the array substrate.

FIG. 18 is a flowchart of a method for manufacturing an array substrate according to some embodiments of the present disclosure. The method includes the following steps.

In step 1701, abase is acquired.

In step 1702, a plurality of transistors manufactured on the base.

The transistor includes:
a first electrode disposed on the base;
an active layer disposed on the base on which the first electrode is provided, wherein the active layer at least covers a partial region of the first electrode;
a first insulating layer disposed on a side of the active layer away from the base, wherein the first insulating layer is provided with a second electrode opening, and an orthographic projection of the second electrode opening on the base and an orthographic projection of the active layer on the base have a first overlapping region;
a gate disposed on a side of the first insulating layer away from the base, wherein the gate is disposed on the first insulating layer, and an orthographic projection of the gate on the base and the orthographic projection of the active layer on the base have a second overlapping region; and
a second electrode disposed on a side of the first insulating layer away from the base or disposed on a side of the first insulating layer close to the base.

The orthographic projection of the second electrode opening on the base overlaps with the orthographic projection of the second electrode on the base, and the second electrode is in contact with the active layer. When the transistor works, the voltage of the first electrode is greater than the voltage of the second electrode, and when the transistor works, the voltage of the first electrode is greater than the voltage of the second electrode.

In summary, according to the method for manufacturing the array substrate provided in the embodiments of the present disclosure, the first electrode having the higher voltage in the first electrode and the second electrode of the transistor is disposed between the active layer and the base in a lower lap manner, and the second electrode having the lower voltage is disposed on the first insulating layer in an upper lap manner or disposed below the first insulating layer in the lower lap manner. When the second electrode is disposed in the upper lap manner, the conducting degree of the surface of the active layer away from the base is greater than the conducting degree of the surface of the active layer close to the base, which can reduce the resistance of the active layer in contact with the second electrode, thereby avoiding the problem that the transistor cannot operate normally due to the too large resistance at the second electrode. When the second electrode is disposed in the lower lap manner, the risk that the active layer is easily damaged at the via hole when the active layer is in contact with the electrode through the via hole can be avoided, thereby solving the problem of poor performance of the array substrate in the related art, and improving the performance of the array substrate.

The term “and/or” in the present disclosure merely describes an association relationship between associated objects, which represents that there may exist three types of relationships. For example, A and/or B represents three situations: A exists alone, A and B exist simultaneously, and B exists alone. The character “/” herein generally represents an “or” relationship between the associated objects before and after the character.

The term “at least one of A and B” in the present disclosure merely describes an association relationship between associated objects, which represents that there may exist three types of relationships. For example, at least one of A and B represents three situations: A exists alone, A and B exist simultaneously, and B exists alone. Similarly, “at least one of A, B, and C” represents seven types of relationships: A exists alone, B exists alone, C exists alone, A and B exist simultaneously, A and C exist simultaneously, C and B exist simultaneously, and A, B, and C exist simultaneously. Similarly, “at least one of A, B, C and D” represents fifteen types of relationships: A exists alone, B exists alone, C exists alone, D exists alone, A and B exist simultaneously, A and C exist simultaneously, A and D exist simultaneously, C and B exist simultaneously, D and B exist simultaneously, C and D exist simultaneously, A, B and C exist simultaneously, A, B and D exist simultaneously, A, C and D exist simultaneously, B, C and D exist simultaneously, and A, B, C and D exist simultaneously.

It should be noted that in the drawings, the dimensions of layers and regions may be exaggerated for clarity of illustration. It is to be further understood that when an element or layer is referred to as being “on” another element or layer, it may be directly on other elements, or an intermediate layer may be present. Additionally, it is to be understood that when an element or layer is referred to as being “under” another element or layer, it may be directly under other elements, or more than one intermediate layer or element may be present. Additionally, it is to be understood that when a layer or element is referred to as being “between” two layers or two elements, it may be the unique layer between the two layers or two elements, or more than one intermediate layer or element may be present. Similar reference numerals indicate similar elements throughout.

In the present disclosure, the terms “first,” “second,” “third,” and “fourth” are used for descriptive purposes only and are not to be construed as indicating or implying relative importance. The term “a plurality of” refers to two or more, unless otherwise expressly specified.

The above descriptions are merely optional embodiments of the present disclosure, and are not intended to limit the present disclosure. Within the spirit and principles of the present disclosure, any modifications, equivalent substitutions, improvements, and the like are within the protection scope of the present disclosure.

1. An array substrate, comprising: a base and a plurality of transistors disposed on the base, wherein the transistor comprises:
a first electrode disposed on the base;
an active layer disposed on the base on which the first electrode is provided, wherein the active layer at least covers a partial region of the first electrode;
a first insulating layer disposed on a side of the active layer away from the base, wherein the first insulating layer is provided with a second electrode opening, wherein an orthographic projection of the second electrode opening on the base and an orthographic projection of the active layer on the base have a first overlapping region;
a gate disposed on a side of the first insulating layer away from the base, wherein the gate is disposed on the first insulating layer, and an orthographic projection of the gate on the base and the orthographic projection of the active layer on the base have a second overlapping region; and
a second electrode disposed on the side of the first insulating layer away from the base or disposed on a side of the first insulating layer close to the base;
wherein the orthographic projection of the second electrode opening on the base overlaps with an orthographic projection of the second electrode on the base, the second electrode is in contact with the active layer, and when the transistor operates, a voltage of the first electrode is greater than a voltage of the second electrode.

2. The array substrate according to claim 1, wherein in the case that the second electrode is disposed on the side of the first insulating layer away from the base, the second electrode is in contact with the active layer through the second electrode opening; and the first insulating layer is further provided with a first electrode opening, wherein an orthographic projection of the first electrode opening on the base and the orthographic projection of the active layer on the base have a third overlapping region, and the third overlapping region overlaps with the first electrode;
the first insulating layer comprises a gate insulating layer disposed between the first electrode opening and the second electrode opening, and an orthographic projection of an edge, covered by the active layer, of the first electrode on the base is within an orthographic projection of the gate insulating layer on the base.

3. The array substrate according to claim 2, wherein
a first distance between an edge of the gate insulating layer at the first electrode opening and the gate in a first direction is positively correlated with a mobility of the active layer, wherein the first direction is an arrangement direction of the first electrode opening and the second electrode opening;
a second distance between an edge of the gate insulating layer at the second electrode opening and the gate in the first direction is positively correlated with the mobility of the active layer.

4. The array substrate according to claim 2, wherein the plurality of transistors comprise a plurality of drive transistors and a plurality of switch transistors, wherein the plurality of drive transistors comprises a first drive transistor, and the plurality of switch transistors comprises a first switch transistor; wherein
a width of the gate insulating layer of the first switch transistor in a first direction is greater than a width of the gate insulating layer of the first drive transistor in the first direction, wherein the first direction is an arrangement direction of the first electrode opening and the second electrode opening.

5. The array substrate according to claim 2, wherein a first distance between an edge of the gate insulating layer at the first electrode opening and the gate in a first direction is greater than a second distance between an edge of the gate insulating layer at the second electrode opening and the gate in the first direction, wherein the first direction is an arrangement direction of the first electrode opening and the second electrode opening.

6. The array substrate according to claim 2, comprising: a buffer layer disposed between the first electrode and the base, wherein the first electrode and the active layer are disposed on the buffer layer.

7. The array substrate according to claim 2, wherein a width of the first electrode opening in a first direction is greater than a width of the second electrode opening in the first direction.

8. The array substrate according to claim 2, wherein the active layer comprises a first end portion, a connection portion, and a second end portion, the connection portion being connected to the first end portion and the second end portion; wherein
an orthographic projection of the first end portion on the base is within the orthographic projection of the first electrode on the base, an orthographic projection of the second end portion on the base is within the orthographic projection of the second electrode on the base, and in a second direction, a width of at least one of the first end portion and the second end portion in the second direction is greater than a width of the connection portion in the second direction, wherein the second direction is a direction perpendicular to an arrangement direction of the first electrode opening and the second electrode opening.

9. The array substrate according to claim 3, wherein the first distance ranges from 2 μm to 4 μm, and the second distance ranges from 2 μm to 4 μm.

10. The array substrate according to any one of claims 1 to 9, wherein the second electrode covers an edge of the second electrode opening away from the gate, and a distance between the second electrode and an edge of the second electrode opening close to the gate is greater than 0.

11. The array substrate according to any one of claims 1 to 9, wherein the transistor further comprises a first conductive block; wherein
the first conductive block is disposed on the base, the active layer is lapped on the first conductive block, and an orthographic projection of the first conductive block on the base overlaps with the first overlapping region.

12. The array substrate according to claim 11, wherein the second electrode covers the second electrode opening, and the orthographic projection of the second electrode opening on the base is within the orthographic projection of the second electrode on the base.

13. The array substrate according to claim 11, wherein the first conductive block and the first electrode are a same layer structure.

14. The array substrate according to claim 2, further comprising: a buffer layer disposed between the active layer and the first electrode, wherein the buffer layer is provided with a buffer layer opening, and the partial region of the first electrode is exposed from the buffer layer opening;
the active layer covers the buffer layer opening and covers the partial region of the first electrode in the buffer layer opening;
the first insulating layer covers a climbing portion of the active layer, wherein the climbing portion of the active layer is a portion of the active layer that covers a hole wall of the buffer layer opening.

15. The array substrate according to claim 14, wherein the transistor further comprises a second conductive block; wherein
the second conductive block and the first electrode are a same layer structure, and an orthographic projection of the second conductive block on the base overlaps with the first overlapping region.

16. The array substrate according to claim 2, wherein the transistor satisfies:
$$L + 2 * T \geq 7 ;$$
wherein L is equal to a width of the gate in a first direction, T is equal to a first distance between an edge of the gate insulating layer at the first electrode opening and the gate, and T is equal to a second distance between an edge of the gate insulating layer at the second electrode opening and the gate.

17. The array substrate according to any one of claims 1 to 9, wherein a mobility of the active layer is greater than or equal to 20 square centimeters per volt per second.

18. The array substrate according to any one of claims 1 to 9, wherein a material of the active layer comprises an indium gallium zinc oxide, and a thickness of the active layer ranges from 300 angstroms to 500 angstroms.

19. A display panel, comprising: the array substrate according to any one of claims 1 to 18.

20. A method for manufacturing an array substrate, comprising:
acquiring a base;
manufacturing a plurality of transistors on the base, wherein the transistor comprises:
a first electrode disposed on the base;
an active layer disposed on the base on which the first electrode is provided, wherein the active layer at least covers a partial region of the first electrode;
a first insulating layer disposed on a side of the active layer away from the base, wherein the first insulating layer is provided with a second electrode opening, wherein an orthographic projection of the second electrode opening on the base and an orthographic projection of the active layer on the base have a first overlapping region;
a gate disposed on a side of the first insulating layer away from the base, wherein the gate is disposed on the first insulating layer, and an orthographic projection of the gate on the base and the orthographic projection of the active layer on the base have a second overlapping region; and
a second electrode disposed on the side of the first insulating layer away from the base or disposed on a side of the first insulating layer close to the base;
wherein the orthographic projection of the second electrode opening on the base overlaps with an orthographic projection of the second electrode on the base, the second electrode is in contact with the active layer, and when the transistor operates, a voltage of the first electrode is greater than a voltage of the second electrode.
